(19) United States
(12) Patent Application Publication
(10) Pub. No.: US 2026/0175562 A1
(43) Pub. Date: Jun. 25, 2026

(54) Electronic Device

(71) Applicant: SEIKO EPSON CORPORATION, Tokyo (JP)

(72) Inventor: Satoru IMAI, Minamimaki (JP)

(21) Appl. No.: 19/431,100

(22) Filed: Dec. 23, 2025

(30) Foreign Application Priority Data
Dec. 25, 2024 (JP) 2024-229397

(51) Int. Cl. B41J 2/045; H05K 1/181; H10W 90/00

(52) U.S. Cl. CPC B41J 2/0451; H05K 1/181; H05K 2201/10734; H10W 90/7295; H10W 90/754

(57) ABSTRACT

An electronic device includes a printed substrate, and including a determination section, and an integrated circuit substrate that is a substrate on which the integrated circuit chip is mounted, in which the integrated circuit substrate is provided with a plurality of terminals, the printed substrate is provided with a plurality of pads and a plurality of wirings, each of the plurality of terminals is coupled to each of the plurality of pads, the plurality of wirings include a constant potential wiring having a constant potential, a first pad of the plurality of pads is coupled to the constant potential wiring, a first terminal of the plurality of terminals is coupled to the first pad, and the determination section determines a presence or absence of a coupling failure between the semiconductor device and the printed substrate, based on a potential of the first terminal.

The present application is based on, and claims priority from JP Application Serial Number 2024-229397, filed Dec. 25, 2024, the disclosure of which is hereby incorporated by reference herein in its entirety.

### BACKGROUND

### 1. Technical Field

The present disclosure relates to an electronic device.

### 2. Related Art

As disclosed in JP-A-2010-271182, a conduction check technology for checking a coupling status between a semiconductor element and a substrate of an electronic device at the time of shipment is known in the related art.

In recent years, the number of terminals has increased due to multifunctionalization of electronic devices, and the package of the semiconductor device built in the electronic device has been miniaturized due to the miniaturization of the electronic device, and as a result, the arrangement of solder balls of a ball grid array (BGA) has been narrowed. Therefore, when the semiconductor device is mounted on the substrate, a coupling area per terminal is also reduced. In such a status, when a temperature cycle progresses over time and the solder ball is peeled off from the substrate, a problem suddenly occurs in the market, but, in the related art, such a problem has not been sufficiently addressed.

### SUMMARY

According to an aspect of the present disclosure, an electronic device includes: a printed substrate; and a semiconductor device mounted on the printed substrate, in which the semiconductor device includes an integrated circuit chip that includes a determination section, and an integrated circuit substrate that is a substrate on which the integrated circuit chip is mounted, the integrated circuit substrate is provided with a plurality of terminals, the printed substrate is provided with a plurality of pads and a plurality of wirings, each of the plurality of terminals is coupled to each of the plurality of pads, the plurality of wirings include a constant potential wiring having a constant potential, a first pad of the plurality of pads is coupled to the constant potential wiring, a first terminal of the plurality of terminals is coupled to the first pad, and the determination section determines a presence or absence of a coupling failure between the semiconductor device and the printed substrate, based on a potential of the first terminal.

### BRIEF DESCRIPTION OF THE DRAWINGS

FIG. 1 is an external perspective view of an electronic device.

FIG. 2 is a view illustrating an example of a functional configuration of the electronic device.

FIG. 3 is a sectional view illustrating a structure of a semiconductor device.

FIG. 4 is a view in which a terminal mounting surface of a package is seen through.

FIG. 5 is a functional block diagram of an integrated circuit chip.

FIG. 6 is a plan view of a part of a printed substrate.

FIG. 7 is a plan view of a part of the printed substrate.

FIG. 8 is a plan view of a part of the printed substrate.

### DESCRIPTION OF EMBODIMENTS

Hereinafter, preferred embodiments of the present disclosure will be described with reference to the drawings. The drawings to be used are for convenience of description. The embodiments which will be described below do not inappropriately limit the contents of the present disclosure described in the claims. In addition, the configurations described below are not necessarily all essential constituent elements of the present disclosure.

Hereinafter, as the electronic device according to the present disclosure, an electronic device according to the present embodiment will be described with reference to a multifunction device having a printing function and a scanning function as an example.

### 1. Structure of Electronic Device

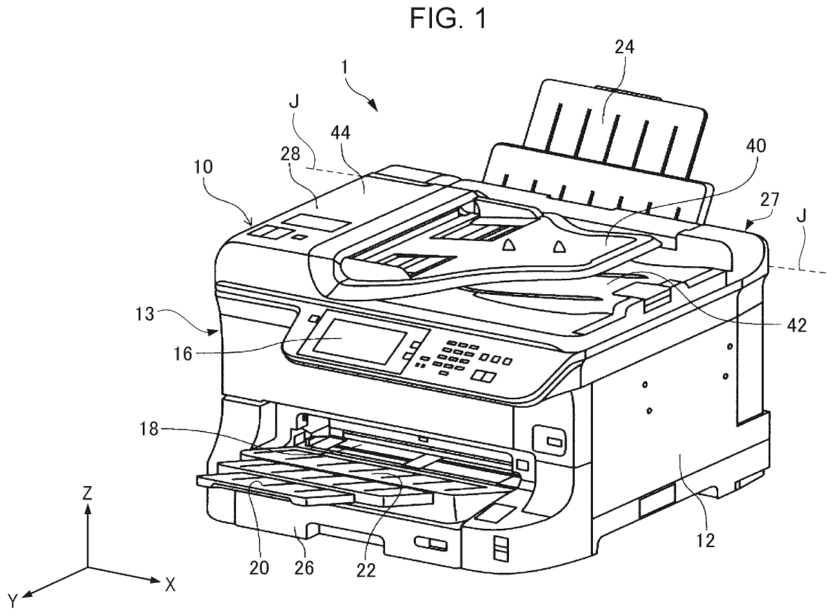

FIG. 1 is an external perspective view of an electronic device 1. In the following, the description will be made using an X direction, a Y direction, and a Z direction which are orthogonal to each other. In addition, a starting point side of the arrow indicating the X direction may be referred to as a −X side, a tip end side thereof may be referred to as a +X side, a starting point side of the arrow indicating the Y direction may be referred to as a −Y side, a tip end side thereof may be referred to as a +Y side, a starting point side of the arrow indicating the Z direction may be referred to as a −Z side, and a tip end side thereof may be referred to as a +Z side.

The electronic device 1 includes a device main body 12 having a substantially rectangular parallelepiped shape as a whole. The device main body 12 includes a recording device 13 that performs recording on a paper, and an image reading device 10 that is provided on the recording device 13 to generate an image by reading information such as a picture, a character, and a photograph formed on a document placed thereon. For example, the image generated by the image reading device 10 is printed on the paper by the recording device 13.

The image reading device 10 includes an auto document feeder (ADF) 27 which is an automatic document feeding device. The ADF 27 is rotatably provided with a back surface side of the device main body 12, which is the −Y side, as a fulcrum of a rotation shaft J, and also has a function as a top plate that can be opened and closed with respect to an upper portion of the device main body 12.

The ADF 27 includes a document transport section 28 including a drive mechanism for transporting documents, a document placement surface 40, and a document discharge surface 42. The document placed on the document placement surface 40 is fed into the image reading device 10 by the document transport section 28, read, and then discharged and placed on the document discharge surface 42.

An operation section 16 is provided at the upper portion of a front surface side of the device main body 12, which is the +Y side, in which the operation section 16 includes a power button, a print setting button, a display panel, and the like for operating the electronic device 1.

A back tray 24 on which the paper is placed is provided on the back surface side of the device main body 12, which is the −Y side. The paper placed on the back tray 24 is fed to the recording device 13 and is recorded.

A paper accommodation section 26 for accommodating a plurality of papers is provided on a bottom surface side of a front tray 22, which is the −Z side. The paper accommodation section 26 is slidably provided at a lower portion of the device main body 12 in the Y direction, and is detachably attached to the device main body 12. The paper placed on the paper accommodation section 26 is fed to the recording device 13 and is recorded.

The front surface side of the device main body 12 is provided with a drawer section 20 that is attached to the front tray 22 and slidable in the Y direction. The paper, which is fed from the back tray 24 or the paper accommodation section 26 to the recording device 13 and recorded, is discharged from an opening portion 18 provided on the front surface side of the device main body 12, and is placed on the front tray 22 and the drawer section 20 in a state where the paper is drawn out from the front tray 22.

### 2. Functional Configuration of Electronic Device

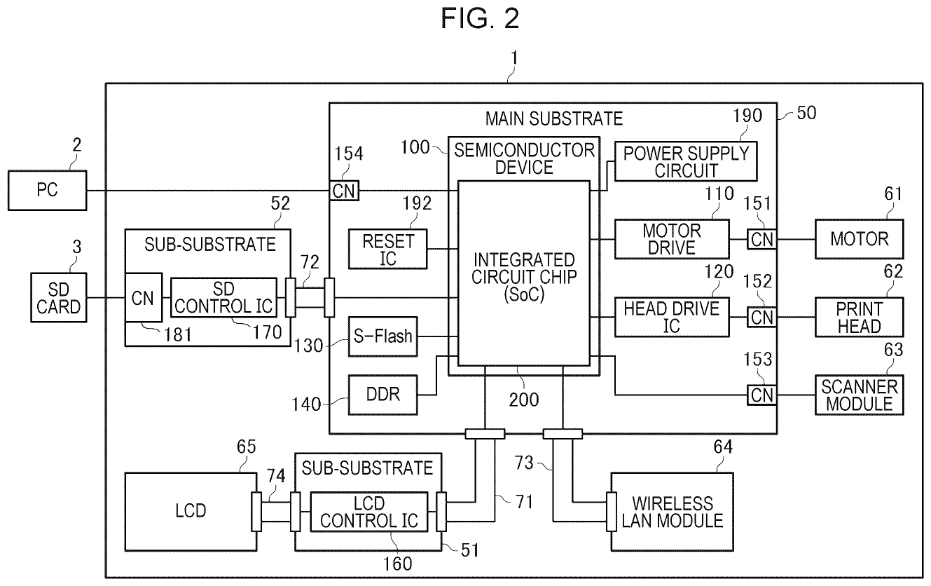

FIG. 2 is a view illustrating an example of a functional configuration of the electronic device 1. As illustrated in FIG. 2, the electronic device 1 includes a main substrate 50, a sub-substrate 51, and a sub-substrate 52. The main substrate 50 and the sub-substrates 51 and 52 are, for example, multilayer printed substrates.

The main substrate 50 has a semiconductor device 100 having an integrated circuit chip 200, a motor driver 110, a head drive IC 120, a serial flash memory 130, a DDR 140, a power supply circuit 190, and a reset IC 192, which are mounted thereon. The DDR is an abbreviation for double-data-rate SDRAM. In addition, the main substrate 50 is provided with connectors 151, 152, 153, and 154.

An LCD control IC 160 is mounted on the sub-substrate 51. The sub-substrate 51 is coupled to the main substrate 50 by a cable 71.

The sub-substrate 52 has an SD control IC 170 and a connector 181 mounted thereon. The sub-substrate 52 is coupled to the main substrate 50 by a cable 72.

Further, the electronic device 1 includes various motors 61, a print head 62, a scanner module 63, a wireless LAN module 64, and an LCD 65. The LAN is an abbreviation for local area network. The LCD is an abbreviation for liquid crystal display.

The motor 61 is coupled to the main substrate 50 via the connector 151 and is driven by the motor driver 110.

The print head 62 is provided in the recording device 13, is coupled to the main substrate 50 via the connector 152, and is driven by the head drive IC 120.

The scanner module 63 is provided in the image reading device 10, is coupled to the main substrate 50 via the connector 153, and is controlled by the integrated circuit chip 200. In addition, the scanner module 63 transmits scan data generated by scanning the document to the integrated circuit chip 200.

The wireless LAN module 64 is a module that performs wireless data communication with an external device of the electronic device 1. The wireless LAN module 64 is coupled to the main substrate 50 via a cable 73 and is controlled by the integrated circuit chip 200. In addition, the wireless LAN module 64 performs USB communication with the integrated circuit chip 200.

The LCD 65 is a display panel included in the operation section 16 and displays various information. The LCD 65 is coupled to the sub-substrate 51 via a cable 74 and is controlled by the LCD control IC 160.

The LCD control IC 160 is a circuit that is coupled to the LCD 65 via the cable 74 and controls the display of various information on the LCD 65. The LCD control IC 160 is controlled by the integrated circuit chip 200.

The SD control IC 170 is a circuit that controls writing or reading of data to and from an SD card 3 inserted into the connector 181. The SD control IC 170 is controlled by the integrated circuit chip 200. In addition, the SD control IC 170 performs USB communication with the integrated circuit chip 200.

The motor driver 110 is a circuit that is coupled to the motor 61 via the connector 151 and drives the motor 61. The motor driver 110 is controlled by the integrated circuit chip 200.

The head drive IC 120 is a circuit that is coupled to the print head 62 via the connector 152 and drives the print head 62. The head drive IC 120 is controlled by the integrated circuit chip 200.

The serial flash memory 130 and the DDR 140 are storage devices that store various types of data, and the writing and reading of data are controlled by the integrated circuit chip 200.

The power supply circuit 190 supplies power to the semiconductor device 100, the motor driver 110, the head drive IC 120, the serial flash memory 130, and the DDR 140. For example, the power supply circuit 190 generates a power supply voltage of several volts (V) to supply the power supply voltage to the semiconductor device 100, the motor driver 110, the head drive IC 120, the serial flash memory 130, and the DDR 140. In addition, the power supply circuit 190 generates a power supply voltage of several tens of volts (V) for driving the motor 61 and the print head 62 to supply the power supply voltage to the motor driver 110 and the head drive IC 120. The motor 61 and the print head 62 are operated by the power supplied from the power supply circuit 190 via the motor driver 110 and the head drive IC 120, respectively. The power supply circuit 190 is controlled by the integrated circuit chip 200.

The reset IC 192 resets the semiconductor device 100 when a determination is made that there is an abnormality by monitoring the power supply voltage of the semiconductor device 100 or the like. The reset IC 192 is controlled by the integrated circuit chip 200.

As described above, the integrated circuit chip 200 is an SoC that controls the motor driver 110, the head drive IC 120, the serial flash memory 130, the DDR 140, the scanner module 63, the wireless LAN module 64, the LCD control IC 160, the SD control IC 170, the power supply circuit 190, and the reset IC 192. The SoC is an abbreviation for system on chip.

Further, the integrated circuit chip 200 is coupled to a PC 2 outside the electronic device 1 via the connector 154, and performs data communication with the PC 2. The connector 154 is, for example, a USB connector.

### 3. Structure of Semiconductor Device

The semiconductor device 100 has a surface-mount package form represented as system in package (SiP), ball grid array (BGA), land grid array (LGA), wafer process package (WPP), and the like. Hereinafter, the structure will be described with an example in which the package form of the semiconductor device 100 is the BGA.

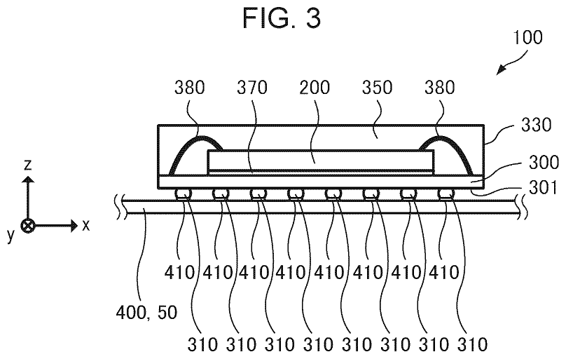

FIG. 3 is a sectional view illustrating a structure of the semiconductor device 100. In the following, the description will be made using an x direction, a y direction, and a z direction that are independent of the X direction, the Y direction, and the Z direction illustrated in FIG. 1 and are orthogonal to each other. In addition, a starting point side of the arrow indicating the x direction may be referred to as a −x side, a tip end side thereof may be referred to as a +x side, a starting point side of the arrow indicating the y direction may be referred to as a −y side, a tip end side thereof may be referred to as a +y side, a starting point side of the arrow indicating the z direction may be referred to as a −z side, and a tip end side thereof may be referred to as a +z side.

As illustrated in FIG. 3, the semiconductor device 100 includes a base substrate 300, the integrated circuit chip 200, and a housing 350.

The housing 350 is located on the +z side of the integrated circuit chip 200 and is bonded to the base substrate 300 so as to cover the integrated circuit chip 200. The housing 350 contains an epoxy resin or the like and protects the integrated circuit chip 200.

The base substrate 300 is located on the −z side of the integrated circuit chip 200. The integrated circuit chip 200 is mounted on the base substrate 300 by a bonding member 370 such as an adhesive. The base substrate 300 and the integrated circuit chip 200 are electrically coupled to each other via a bonding wire 380.

The base substrate 300 is provided with a plurality of wiring patterns and a plurality of electrodes (not illustrated). The bonding wire 380 is electrically coupled to an electrode (not illustrated) formed on a surface of the base substrate 300 on the +z side. In addition, a plurality of electrodes (not illustrated) are provided on a surface of the base substrate 300 on the −z side. Each of the plurality of electrodes provided on the surface of the base substrate 300 on the −z side is attached with a solder ball 310. That is, a plurality of solder balls 310, which are a plurality of terminals, are provided on the base substrate 300. A printed substrate 400, which is the main substrate 50 of FIG. 2, is provided with a plurality of pads 410 and a plurality of wirings (not illustrated), and each of the plurality of solder balls 310 is coupled to each of the plurality of pads 410. The base substrate 300 is electrically coupled to the printed substrate 400 by the plurality of solder balls 310. The plurality of solder balls 310 form a so-called ball grid array that electrically and mechanically couples the base substrate 300 and the printed substrate 400 to each other. In the following description, the surface of the base substrate 300 on the −z side, to which the plurality of solder balls 310 are attached, is referred to as a terminal mounting surface 301.

A package 330 is formed by a ball grid array including the base substrate 300, the housing 350, and the plurality of solder balls 310. The integrated circuit chip 200 is mounted on the base substrate 300 which is an internal substrate of the package 330.

In the semiconductor device 100 formed as described above, a signal input to the semiconductor device 100 via the plurality of solder balls 310, which are provided on the terminal mounting surface 301, propagates via the electrode and the wiring pattern provided on the base substrate 300 and the bonding wire 380, and is input to the integrated circuit chip 200. In addition, the signal output from the integrated circuit chip 200 is input to the plurality of pads 410 of the printed substrate 400 via the bonding wire 380, the electrode and the wiring pattern provided on the base substrate 300, and the plurality of solder balls 310.

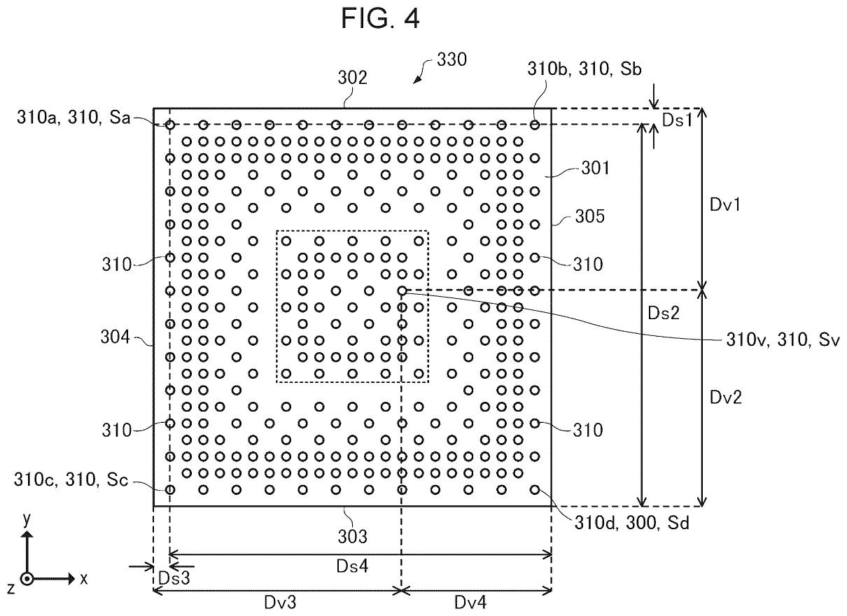

FIG. 4 is a view in which the terminal mounting surface 301 of the base substrate 300 of the package 330 is seen through from the +z side. As illustrated in FIG. 4, the base substrate 300 of the package 330 has a side 302 extending in the x direction, a side 303 extending in the x direction and opposite to the side 302, a side 304 extending in the y direction, and a side 305 extending in the y direction and opposite to the side 304. Each of the sides 304 and 305 intersects the sides 302 and 303. That is, the base substrate 300 has a substantially rectangular shape having the sides 302, 303, 304, and 305 as an outer periphery.

As illustrated in FIG. 4, the terminal mounting surface 301 of the base substrate 300 has the plurality of solder balls 310 that are distributed in 23 rows in the y direction and disposed in a lattice shape, and a maximum of 23 solder balls 310 that are disposed in each row. The solder balls 310 coupled to the motor driver 110, the head drive IC 120, the serial flash memory 130, the DDR 140, and the connectors 151, 152, 153, and 154 are disposed at the outermost peripheral portion of the terminal mounting surface 301 or at a position close to the outermost peripheral portion. The plurality of solder balls 310 disposed at the outermost periphery have a wide arrangement interval in order to secure a space for allowing the wirings coupled to the inside solder balls 310 to pass therethrough. In addition, on the terminal mounting surface 301, a power supply voltage is supplied to the plurality of solder balls 310 disposed in a region near the center surrounded by a broken line.

### 4. Functional Configuration of Integrated Circuit Chip

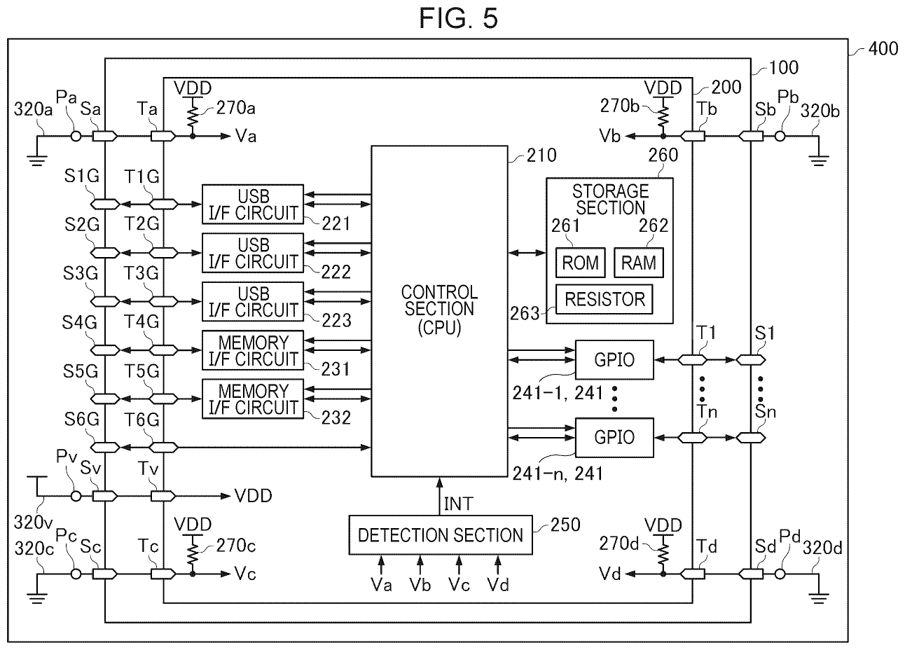

FIG. 5 is a functional block diagram of the integrated circuit chip 200. As illustrated in FIG. 5, the integrated circuit chip 200 includes a control section 210, USB interface circuits 221, 222, and 223, memory interface circuits 231 and 232, n GPIOs 241-1 to 241-n, a detection section 250, a storage section 260, and resistors 270a, 270b, 270c, and 270d. The GPIO is an abbreviation for general-purpose input/output. The integrated circuit chip 200 may be formed by omitting or changing a part of the components in FIG. 5, or adding other components.

The USB interface circuit 221 is coupled to a terminal group T1G including a plurality of terminals of the integrated circuit chip 200. The USB interface circuit 222 is coupled to a terminal group T2G including a plurality of terminals of the integrated circuit chip 200. The USB interface circuit 223 is coupled to a terminal group T3G including a plurality of terminals of the integrated circuit chip 200. The memory interface circuit 231 is coupled to a terminal group T4G including a plurality of terminals of the integrated circuit chip 200. The memory interface circuit 232 is coupled to a terminal group T5G including a plurality of terminals of the integrated circuit chip 200. The control section 210 is coupled to a terminal group T6G including a plurality of terminals of the integrated circuit chip 200.

The terminal groups T1G to T6G of the integrated circuit chips 200 are coupled to the terminal groups SlG to S6G of the semiconductor device 100, respectively. Each terminal included in the terminal groups SlG to S6G of the semiconductor device 100 is the solder ball 310 provided on the terminal mounting surface 301. The terminal group SlG of the semiconductor device 100 is coupled to the PC 2 via the connector 154. The terminal group S2G of the semiconductor device 100 is coupled to the SD control IC 170 via the cable 72. The terminal group S3G of the semiconductor device 100 is coupled to the wireless LAN module 64 via the cable 73. The terminal group S4G of the semiconductor device 100 is coupled to the serial flash memory 130. The terminal group S5G of the semiconductor device 100 is coupled to the DDR 140. The terminal group S6G of the semiconductor device 100 is coupled to the LCD control IC 160.

The n GPIOs 241-1 to 241-n are coupled to the n terminals S1 to Sn of the semiconductor device 100, respectively. The n terminals Ti to Tn of the integrated circuit chip 200 are coupled to the n terminals S1 to Sn of the semiconductor device 100, respectively. The terminals S1 to Sn of the semiconductor device 100 are the solder balls 310 provided on the terminal mounting surface 301.

The storage section 260 includes a ROM 261, a RAM 262, and a register 263. The ROM is an abbreviation for read only memory, and the RAM is an abbreviation for random access memory. The ROM 261 stores various programs and predetermined data. The RAM 262 is used as a work region of the control section 210, and stores a program or data read from the ROM 261, and data temporarily generated by the control section 210. The register 263 stores various setting data and the like.

The control section 210 performs various controls, image processing, and the like. In the present embodiment, the control section 210 is a processor such as a CPU, and performs various controls, image processing, and the like by executing a program (not illustrated) stored in the ROM 261. However, some processing of the control section 210 may be realized by hardware.

Specifically, the control section 210 performs various controls on the motor driver 110, the head drive IC 120, the scanner module 63, and the LCD control IC 160.

Further, the control section 210 performs USB communication with the PC 2 by controlling the USB interface circuit 221. In addition, the control section 210 performs USB communication with the SD control IC 170 by controlling the USB interface circuit 222. In addition, the control section 210 performs USB communication with the wireless LAN module 64 by controlling the USB interface circuit 223. In addition, the control section 210 transmits the image data to the LCD control IC 160.

Further, the control section 210 controls the memory interface circuit 231 to write or read data to or from the serial flash memory 130. In addition, the control section 210 controls the memory interface circuit 232 to write or read data to or from the DDR 140.

For example, the control section 210 receives the image data for printing from the PC 2 via the USB interface circuit 221 and writes the image data to the serial flash memory 130 or the DDR 140. In addition, for example, the control section 210 receives the image data stored in the SD card 3 from the SD control IC 170 via the USB interface circuit 222, and writes the image data to the serial flash memory 130 or the DDR 140. In addition, for example, the control section 210 receives the image data from the wireless LAN module 64 via the USB interface circuit 223 and writes the image data to the serial flash memory 130 or the DDR 140. Further, for example, the control section 210 acquires scan data from the scanner module 63, performs image processing on the scan data to generate image data, and writes the image data to the serial flash memory 130 or the DDR 140.

Further, for example, the control section 210 performs image processing on the scan data to generate image data, and writes the image data to the serial flash memory 130 or the DDR 140.

Further, for example, the control section 210 reads the image data for printing from the serial flash memory 130 or the DDR 140, performs image processing for printing to generate print data, and outputs the print data to the head drive IC 120. In addition, for example, the control section 210 reads the image data from the serial flash memory 130 or the DDR 140 and transmits the image data to the PC 2 via the USB interface circuit 221. In addition, for example, the control section 210 reads the image data from the serial flash memory 130 or the DDR 140 and transmits the image data to the SD control IC 170 via the USB interface circuit 222. In addition, for example, the control section 210 reads the image data from the serial flash memory 130 or the DDR 140 and transmits the image data to the wireless LAN module 64 via the USB interface circuit 223.

Further, the control section 210 controls the input and output of each of the GPIOs 241-1 to 241-n. Specifically, the control section 210 controls each of the GPIOs 241-1 to 241-n to function as any of an input/output circuit, an input circuit, and an output circuit. For example, the control section 210 may control the GPIO 241-k among the GPIOs 241-3 to 241-n and the terminal Tl to function as output circuits, respectively, and may output control signals to the power supply circuit 190 and the reset IC 192 from the terminals Tk and Tl, respectively.

As illustrated in FIG. 5, a terminal Tv of the integrated circuit chip 200 is coupled to a terminal Sv of the semiconductor device 100. The terminal Sv of the semiconductor device 100 is coupled to a pad Pv provided on the printed substrate 400. The pad Pv is any of the plurality of pads 410 illustrated in FIG. 3. In the printed substrate 400, the pad Pv is coupled to a wiring 320v. The wiring 320v is a power supply wiring, and a power supply voltage VDD of several volts (V) generated by the power supply circuit 190 illustrated in FIG. 2 is supplied from the terminal Sv to the semiconductor device 100. Each section of the integrated circuit chip 200 operates while being supplied with the power supply voltage VDD.

Further, terminals Ta, Tb, Tc, and Td of the integrated circuit chip 200 are coupled to terminals Sa, Sb, Sc, and Sd of the semiconductor device 100, respectively. The terminals Sa, Sb, Sc, and Sd of the semiconductor device 100 are the solder balls 310 provided on the terminal mounting surface 301, and are coupled to the pads Pa, Pb, Pc, and Pd provided on the printed substrate 400, respectively. The pads Pa, Pb, Pc, and Pd are any of the plurality of pads 410 illustrated in FIG. 3, respectively. In the printed substrate 400, the pads Pa, Pb, Pc, and Pd are coupled to wirings 320a, 320b, 320c, and 320d, respectively. The wirings 320a, 320b, 320c, and 320d are constant potential wirings having a constant potential, for example, a ground potential.

In addition, the terminals Ta, Tb, Tc, and Td of the integrated circuit chip 200 are coupled to supply lines of the power supply voltage VDD via the resistors 270a, 270b, 270c, and 270d, respectively. That is, the resistors 270a, 270b, 270c, and 270d function as pull-up resistors. Therefore, the terminals Sa and Ta have a ground potential when the coupling between the terminal Sa and the pad Pa is normal, but have a power supply potential that is pulled up by the resistor 270a when the coupling failure occurs. Similarly, the terminals Sb and Tb have a ground potential when the coupling between the terminal Sb and the pad Pb is normal, but have a power supply potential that is pulled up by the resistor 270b when the coupling failure occurs. Similarly, the terminals Sc and Tc have a ground potential when the coupling between the terminal Sc and the pad Pc is normal, but have a power supply potential that is pulled up by the resistor 270c when the coupling failure occurs. Similarly, the terminals Sd and Td have a ground potential when the coupling between the terminal Sd and the pad Pd is normal, but have a power supply potential that is pulled up by the resistor 270d when the coupling failure occurs.

In the present embodiment, the control section 210 functions as a determination section that determines the presence or absence of a coupling failure between the semiconductor device 100 and the printed substrate 400 based on the potentials of the terminals Sa, Sb, Sc, and Sd of the semiconductor device 100, that is, the potentials of the terminals Ta, Tb, Tc, and Td of the integrated circuit chip 200. That is, the control section 210 determines that the coupling between the semiconductor device 100 and the printed substrate 400 is normal when all the potentials of the terminals Ta, Tb, Tc, and Td are at a low level, and determines that the coupling between the semiconductor device 100 and the printed substrate 400 is abnormal when at least one potential of the terminals Ta, Tb, Tc, and Td is at a high level.

In the present embodiment, the detection section 250 outputs an interrupt signal INT to the control section 210, which is the determination section, when at least one of the potentials of the terminals Sa, Sb, Sc, and Sd, that is, the potentials of the terminals Ta, Tb, Tc, and Td of the integrated circuit chip 200 change from the low level to the high level. When the interrupt signal INT is input, the control section 210 determines that the coupling failure occurs between the semiconductor device 100 and the printed substrate 400. Accordingly, the control section 210 does not need to determine the presence or absence of the coupling failure until the interrupt signal INT is input, so that other processing can be performed with priority.

The control section 210 performs predetermined processing when the coupling failure is detected. For example, when a determination is made that the coupling failure occurs, the control section 210 may stop the supply of power from the power supply circuit 190 to the motor driver 110 and the motor 61. For example, the recording device 13 includes a transport motor, which transports a paper serving as a medium, as the motor 61, and when a determination is made that the coupling failure occurs, the control section 210 may stop the supply of power from the power supply circuit 190 to the transport motor. When the coupling failure occurs between the semiconductor device 100 and the printed substrate 400, the recording device 13 may not perform normal printing, and thus the paper is not wasted by stopping the supply of power to the transport motor.

Further, for example, when a determination is made that the coupling failure occurs, the control section 210 may transmit the control signal to the reset IC 192, and the reset IC 192 may receive the control signal and reset the semiconductor device 100. When the semiconductor device 100 is reset, the detection section 250 outputs again the interrupt signal INT to the control section 210, and the control section 210 detects the coupling failure, so that the control section 210 transmits the control signal to the reset IC 192 again. That is, when the control section 210 detects the coupling failure once, the semiconductor device 100 is reset repeatedly, so that various functions of the semiconductor device 100 are stopped, thereby reducing the possibility of malfunction due to the coupling failure.

The control section 210 may determine the presence or absence of the coupling failure between the semiconductor device 100 and the printed substrate 400 based on logic levels of the potentials of the terminals Sa, Sb, Sc, and Sd at a timing immediately after the terminal Sv of the semiconductor device 100 reaches the power supply potential by the power supply circuit 190 starting to supply the power supply voltage VDD to the semiconductor device 100. That is, the control section 210 may determine the presence or absence of the coupling failure each time the power is turned on. Accordingly, the control section 210 can quickly detect and cope with the coupling failure due to age deterioration.

The terminals Sa, Sb, Sc, and Sd are preferably four solder balls 310 disposed at the outermost periphery of the base substrate 300, which are likely to have a coupling failure due to age deterioration, among the plurality of solder balls 310 provided on the base substrate 300. Further, the terminals Sa, Sb, Sc, and Sd are preferably four solder balls 310 disposed at four corners of the base substrate 300, which are likely to have an initial coupling failure due to age deterioration.

For example, as illustrated in FIG. 4, the terminal Sa is a solder ball 310a closest to a corner where the side 302 and the side 304 of the base substrate 300 intersect. Therefore, none of the plurality of solder balls 310, which is the plurality of terminals of the semiconductor device 100, are disposed between the terminal Sa and the side 302 in the y direction from the side 303 toward the side 302. In addition, none of the plurality of solder balls 310, which is the plurality of terminals of the semiconductor device 100, are disposed between the terminal Sa and the side 304 in the −x direction from the side 305 toward the side 304.

Further, as illustrated in FIG. 4, the terminal Sb is a solder ball 310b closest to a corner where the side 302 and the side 305 of the base substrate 300 intersect. Therefore, none of the plurality of terminals of the semiconductor device 100 is disposed between the terminal Sb and the side 305 in the x direction from the side 304 toward the side 305. In addition, none of the plurality of terminals of the semiconductor device 100 is disposed between the terminal Sb and the side 302 in the y direction from the side 303 toward the side 302.

Further, as illustrated in FIG. 4, the terminal Sc is a solder ball 310c closest to a corner where the side 303 and the side 304 of the base substrate 300 intersect. Therefore, none of the plurality of terminals of the semiconductor device 100 is disposed between the terminal Sc and the side 304 in the −x direction from the side 305 toward the side 304. In addition, none of the plurality of terminals of the semiconductor device 100 is disposed between the terminal Sc and the side 303 in the −y direction from the side 302 toward the side 303.

Further, as illustrated in FIG. 4, the terminal Sd is a solder ball 310d closest to a corner where the side 303 and the side 305 of the base substrate 300 intersect. Therefore, none of the plurality of terminals of the semiconductor device 100 is disposed between the terminal Sd and the side 303 in the −y direction from the side 302 toward the side 303. In addition, none of the plurality of terminals of the semiconductor device 100 is disposed between the terminal Sd and the side 305 in the x direction from the side 304 toward the side 305.

However, when the power supply voltage VDD is not supplied to the semiconductor device 100, the control section 210 cannot determine the coupling failure between the terminals Sa, Sb, Sc, and Sd and the pads Pa, Pb, Pc, and Pd. Therefore, the terminal Sv, which shares the power supply voltage VDD, is preferably disposed at a place where the terminal Sv is less likely to have a coupling failure compared to the terminals Sa, Sb, Sc, and Sd due to age deterioration, among the plurality of solder balls 310 provided on the base substrate 300. That is, in the base substrate 300, the terminal Sv is preferably disposed closer to the center than each of the terminals Sa, Sb, Sc, and Sd.

For example, in FIG. 4, since the terminal Sa is disposed close to the side 302, a shortest distance Ds1 between the terminal Sa and the side 302 is shorter than a shortest distance Ds2 between the terminal Sa and the side 303. Therefore, in a relationship between the arrangement of the terminal Sa and the arrangement of the terminal Sv, it is preferable that a shortest distance Dv1 between the terminal Sv and the side 302 is longer than the shortest distance Ds1 between the terminal Sa and the side 302, and a shortest distance Dv2 between the terminal Sv and the side 303 is longer than the shortest distance Ds1 between the terminal Sa and the side 302.

Further, in FIG. 4, since the terminal Sa is disposed close to the side 304, a shortest distance Ds3 between the terminal Sa and the side 304 is shorter than a shortest distance Ds4 between the terminal Sa and the side 305. Therefore, in the relationship between the arrangement of the terminal Sa and the arrangement of the terminal Sv, it is preferable that a shortest distance Dv3 between the terminal Sv and the side 304 is longer than the shortest distance Ds3 between the terminal Sa and the side 304, and a shortest distance Dv4 between the terminal Sv and the side 305 is longer than the shortest distance Ds3 between the terminal Sa and the side 304.

The relationship between the arrangement of each of the terminals Sb, Sc, and Sd and the arrangement of the terminal Sv is the same as the relationship between the arrangement of the terminal Sa and the arrangement of the terminal Sv, and as a result, the terminal Sv is preferably disposed in a region near the center of the base substrate 300 surrounded by the broken line in FIG. 4, which is away from the four corners of the base substrate 300.

In FIGS. 4 and 5, the semiconductor device 100 is provided with four terminals Sa, Sb, Sc, and Sd for detecting the coupling failure with the printed substrate 400, but may be provided with at least one of the terminals Sa, Sb, Sc, and Sd.

### 5. Layout of Pads and Wirings of Printed Substrate

The integrated circuit chip 200 is mounted on the small package 330, thereby realizing reduction in the size and cost of the semiconductor device 100. However, in the small package 330, an interval between the solder balls 310 is narrowed, and an interval between the pads 410 provided on the printed substrate 400 is also narrowed. Therefore, it is difficult to extend the large number of wirings coupled to each pad 410 to an outside of the mounting region of the semiconductor device 100 through a space between the large number of pads 410. Therefore, in the present embodiment, shapes of some of the pads 410 are devised in order to secure a space for allowing each wiring to pass therethrough in the printed substrate 400.

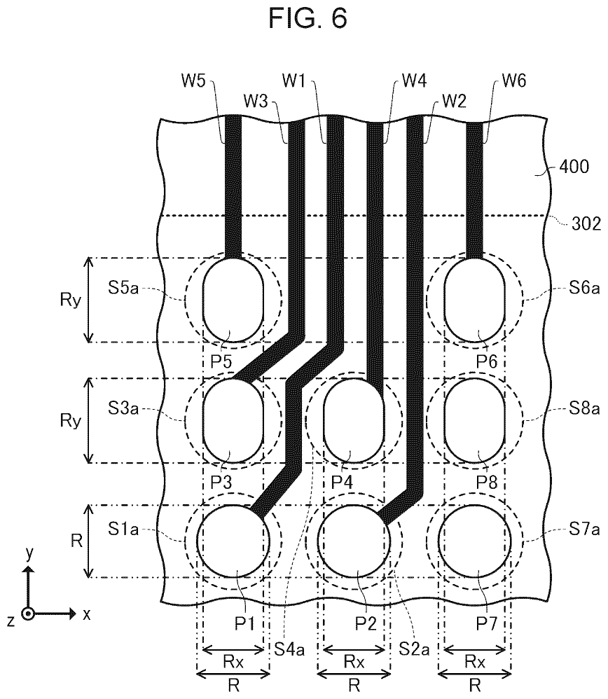

FIG. 6 is a plan view of a part of the printed substrate 400 when viewed from the +z side. As illustrated in FIG. 3, the printed substrate 400 is provided with the plurality of pads 410, and as illustrated in FIG. 6, the plurality of pads 410 include pads P1, P2, P3, P4, P5, P6, P7, and P8. Each of the plurality of pads 410 is provided at a position corresponding to each of the plurality of solder balls 310, which are the plurality of terminals of the semiconductor device 100, and the semiconductor device 100 is mounted on the printed substrate 400 by coupling each solder ball 310 to each pad 410. When the semiconductor device 100 is mounted on the printed substrate 400, each of the plurality of pads 410 provided on the printed substrate 400 is electrically coupled to any one of the terminals of the semiconductor device 100 and any one of the terminals of the integrated circuit chip 200.

As illustrated in FIG. 6, the pads P1, P2, P3, P4, P5, P6, P7, and P8 are coupled to the terminals S1a, S2a, S3a, S4a, S5a, S6a, S7a, and S8a of the semiconductor device 100, respectively.

Each of the pads P1, P2, and P7 has a circular shape, and each of the pads P3, P4, P5, P6, and P8 has an elliptical shape. The elliptical shape has a diameter Ry in the y direction, which is larger than a diameter R of the circular shape, and a diameter Rx in the x direction, which is smaller than a diameter R of the circular shape. That is, the pads P3, P4, P5, P6, and P8 have an elliptical shape in the y direction, in which an area of each of the pads P3, P4, P5, P6, and P8 is equal to an area of each of the pads P1, P2, and P7. Therefore, a coupling strength between each of the terminals S3a, S4a, S5a, S6a, S7a, and S8a and each of the pads P3, P4, P5, P6, and P8 can be made equivalent to a coupling strength between each of the terminals S1a, S2a, and S7a and each of the pads P1, P2, and P7. In the present embodiment, the shapes of the pads P3, P4, P5, P6, and P8 are described as an elliptical shape, but the shapes of the pads P3, P4, P5, P6, and P8 may be an elliptical shape having the equivalent area.

In FIG. 6, the side 302 of the terminal mounting surface 301 is indicated by a broken line. That is, the pad P5 and the pad P6 are arranged along the side 302. The pad P5 and the pad P6 are adjacent to each other in the x direction from the side 304 toward the side 305. In addition, none of the plurality of pads 410 is disposed between the pad P5 and the side 302 in the y direction from the side 303 toward the side 302. Similarly, none of the plurality of pads 410 is disposed between the pad P6 and the side 302 in the y direction. That is, each of the pads P5 and P6 is coupled to an outermost peripheral solder ball 310 provided on the terminal mounting surface 301.

Further, in the x direction, the pad P3 and the pad P4 are adjacent to each other, and the pad P4 and the pad P8 are adjacent to each other. Further, in the x direction, the pad P1 and the pad P2 are adjacent to each other, and the pad P2 and the pad P7 are adjacent to each other.

Further, the pad P1, the pad P3, and the pad P5 at least partially overlap each other in the y direction. In addition, the pad P2 and the pad P4 at least partially overlap each other in the y direction. Further, the pad P7, the pad P8, and the pad P6 at least partially overlap each other in the y direction. That is, the pad 410 is not disposed on the −y side of the pad P4 between the pad P5 and the pad P6. Therefore, a shortest distance between the pad P5 and the pad P6 is longer than a shortest distance between the pad P1 and the pad P2. In addition, the shortest distance between the pad P5 and the pad P6 is longer than a shortest distance between the pad P3 and the pad P4. Further, as described above, since the pads P5 and P6 have an elliptical shape in the y direction, a wide space is provided between the pads P5 and P6.

As illustrated in FIG. 6, the printed substrate 400 is provided with a plurality of wirings including wirings W1, W2, W3, W4, W5, and W6. The wirings W1, W2, W3, W4, W5, and W6 are coupled to the pads P1, P2, P3, P4, P5, and P6, respectively.

The wiring W5 extends from the pad P5 in the y direction. The wiring W1 extends in the y direction while passing through between the pad P3 and the pad P4 from the pad P1. The wiring W3 extends in the y direction while passing through between the pad P5 and the wiring W1 and passing through between the wiring W5 and the wiring W1, from the pad P3. The wiring W2 extends in the y direction while passing through between the pad P4 and the pad P5 from the pad P2. The wiring W4 extends in the y direction while passing through between the wiring W1 and the wiring W2 from the pad P4. The wiring W6 extends from the pad P6 in the y direction. That is, the wiring W1 passes through between the pad P3 and the pad P4, the wiring W2 passes through between the pad P4 and the pad P8, the wirings W1 and W3 pass through between the pad P4 and the pad P5, and the wirings W1, W2, W3, and W4 pass through between the pad P5 and the pad P6.

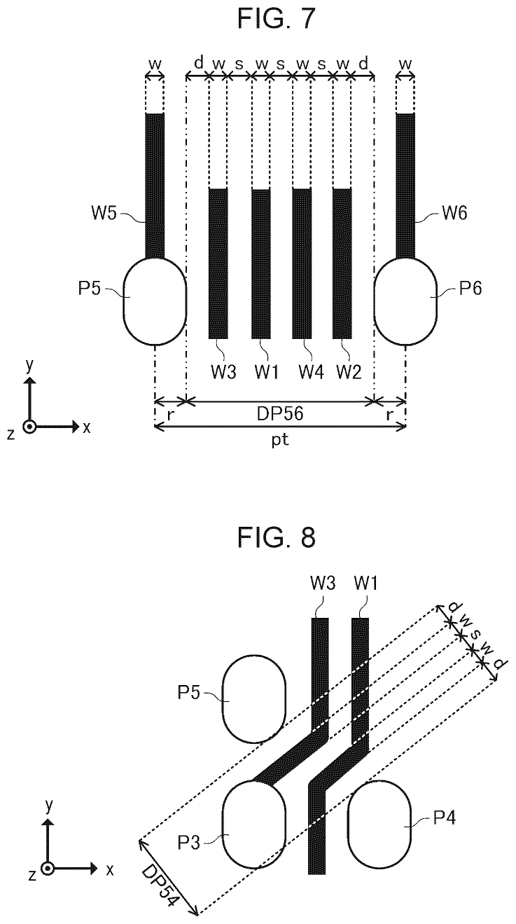

There are certain constraints for the arrangement of the pads P1 to P8 and the wirings W1 and W2, and four wirings W1 to W4 need to pass through between the pad P5 and the pad P6 while satisfying the constraints. FIG. 7 is a view illustrating only a part of the pads P5 and P6 and the wirings W1 to W6. A pitch of the pads P1 to P8 is determined by a pitch of the solder balls 310, and a pitch pt between the pad P5 and the pad P6 is, for example, 1 mm. On the other hand, due to manufacturing limitations and the like, a wiring width w, a wiring interval s, a pad-wiring interval d, and a pad radius r have a minimum value. For example, the minimum value of the wiring width w is 0.080 mm, the minimum value of the wiring interval s is 0.090 mm, the minimum value of the pad-wiring interval d is 0.100 mm, and the minimum value of the pad radius r is 0.100 mm.

In this case, since the minimum value of the wiring width w is smaller than the minimum value of the wiring interval s, a width of the wiring W1, a width of the wiring W2, a width of the wiring W3, and a width of the wiring W4 between the pad P5 and the pad P6 can be smaller than an interval between the wiring W3 and the wiring W1, an interval between the wiring W1 and the wiring W4, and an interval between the wiring W4 and the wiring W2. In addition, since the minimum value of the wiring interval s is smaller than the minimum value of the pad-wiring interval d, the interval between the wiring W3 and the wiring W1, the interval between the wiring W1 and the wiring W4, and the interval between the wiring W4 and the wiring W2 can be smaller than an interval between the pad P5 and the wiring W3 and an interval between the pad P6 and the wiring W2.

For example, when the widths of the wirings W1, W2, W3, and W4 are each 0.080 mm, which is the minimum value of the wiring width w, the interval between the wiring W3 and the wiring W1, the interval between the wiring W1 and the wiring W4, and the interval between the wiring W4 and the wiring W2 are each 0.090 mm, which is the minimum value of the wiring interval s, and the interval between the pad P5 and the wiring W3 and the interval between the pad P6 and the wiring W2 are each 0.100 mm, which is the minimum value of the pad-wiring interval d, and a distance DP56 between the pad P5 and the pad P6 satisfies 0.080 mm×4+0.090 mm×3+0.100 mm×2=0.790 mm. Therefore, when the radii of the pads P5 and P6 are each 0.100 mm, which is the minimum value of the pad radius r, a distance between the center of the pad P5 and the center of the pad P6 satisfies 0.790 mm+0.100 mm×2=0.990 mm and is within 1 mm, which is the pitch pt, so that four wirings W1 to W4 can pass through between the pad P5 and the pad P6. In this case, since the difference between 1 mm, which is the pitch pt, and 0.990 mm, which is the distance between the center of the pad P5 and the center of the pad P6, is 0.010 mm, for example, when the interval between the wiring W3 and the wiring W1 is 0.093 mm, the interval between the wiring W1 and the wiring W4 is 0.093 mm, and the interval between the wiring W4 and the wiring W2 is 0.094 mm, the distance between the center of the pad P5 and the center of the pad P6 can coincide with 1 mm, which is the pitch pt.

Further, two wirings W1 and W3 need to pass through between the pad P5 and the pad P4 while satisfying the constraints. FIG. 8 is a view illustrating only a part of the pads P3, P4, and P5 and the wirings W1 and W3.

As described above, the minimum value of the wiring width w is smaller than the minimum value of the wiring interval s, and thus the width of the wiring W3 and the width of the wiring W1 can be smaller than the interval between the wiring W3 and the wiring W1. In addition, since the minimum value of the wiring interval s is smaller than the minimum value of the pad-wiring interval d, the interval between the wiring W3 and the wiring W1 can be smaller than the interval between the pad P5 and the wiring W3 and the interval between the pad P4 and the wiring W1.

For example, when the widths of the wirings W1 and W3 are each 0.080 mm, which is the minimum value of the wiring width w, the interval between the wiring W3 and wiring W1 is 0.090 mm, which is the minimum value of the wiring interval s, and the interval between the pad P5 and the wiring W3 and the interval between the pad P4 and the wiring W1 are each 0.100 mm, which is the minimum value of the pad-wiring interval d, a distance DP54 between the pad P5 and the pad P4 satisfies 0.080 mm×2+0.090 mm×1+0.100 mm×2=0.45 mm. In fact, when the pads P3, P4, and P5 are disposed at the pitch pt of 1 mm, the distance DP54 between the pad P5 and the pad P4 is 0.4557 mm, so that two wirings W1 and W3 can pass through between the pad P4 and the pad P5.

In addition, in the arrangement of the pads P1 to P8 and the wirings W1 to W2 illustrated in FIG. 6, a shortest distance between the pad P5 and the wiring W3, a shortest distance between the pad P3 and the wiring W1, a shortest distance between the pad P4 and the wiring W1, a shortest distance between the pad P4 and the wiring W2, a shortest distance between the pad P6 and the wiring W2, a shortest distance between the pad P7 and the wiring W2, and a shortest distance between the pad P8 and the wiring W2 are longer than a shortest distance between the wiring W3 and the wiring W1, a shortest distance between the wiring W1 and the wiring W4, and a shortest distance between the wiring W4 and the wiring W2. For example, the shortest distance between the pad P5 and the wiring W3, the shortest distance between the pad P3 and the wiring W1, the shortest distance between the pad P4 and the wiring W1, the shortest distance between the pad P4 and the wiring W2, the shortest distance between the pad P6 and the wiring W2, the shortest distance between the pad P7 and the wiring W2, and the shortest distance between the pad P8 and the wiring W2 are 0.100 mm, which is the minimum value of the pad-wiring interval d. On the other hand, the shortest distance between the wiring W3 and the wiring W1, the shortest distance between the wiring W1 and the wiring W4, and the shortest distance between the wiring W4 and the wiring W2 are 0.090 mm, which is the minimum value of the wiring interval s. As described above, by increasing the shortest distance between each pad and each wiring, an arrangement region of the solder ball 310 coupled to each pad is sufficiently secured.

The terminal Sa is an example of a “first terminal”, and the terminal Sv is an example of a “second terminal”. The pad Pa is an example of a “first pad”, and the pad Pv is an example of a “second pad”. The base substrate 300 is an example of an “integrated circuit substrate”. The side 302 is an example of a “first side”, the side 303 is an example of a “second side”, the side 304 is an example of a “third side”, and the side 305 is an example of a “fourth side”. The y direction is an example of a “first direction”, and the x direction is an example of a “second direction”. The low level is an example of a “first logic level”, and the high level is an example of a “second logic level”.

### 6. Operational Effect

As described above, according to the electronic device 1 according to the present embodiment, when at least one of the terminals Sa, Sb, Sc, and Sd provided on the base substrate 300 of the semiconductor device 100 is peeled off from the printed substrate 400, at least one potential of the terminals Sa, Sb, Sc, and Sd is changed, so that the control section 210 can detect the coupling failure between the semiconductor device 100 and the printed substrate 400 based on the potential. Since the semiconductor device 100 is built in with the control section 210, the inspection of the coupling failure can be performed at any timing, and thus the coupling failure between the semiconductor device 100 and the printed substrate 400 caused by the age deterioration can be detected quickly. Further, since the semiconductor device 100 is built in with the control section 210, it is not necessary to mount a circuit for detecting the coupling failure between the semiconductor device 100 and the printed substrate 400 on the printed substrate 400, thereby reducing the cost of the printed substrate 400.

Further, according to the electronic device 1 according to the present embodiment, when warpage occurs in the base substrate 300 of the semiconductor device 100 due to age deterioration, the terminals Sa, Sb, Sc, and Sd are provided at four corners of the base substrate 300, which are places where the probability of coupling failure is the highest, so that the accuracy of detecting the coupling failure can be improved.

Further, according to the electronic device 1 according to the present embodiment, the terminal Sv coupled to the power supply wiring is provided in a central region of the base substrate 300 of the semiconductor device 100, and thus the possibility that the terminal Sv is peeled off before the terminals Sa, Sb, Sc, and Sd is low. Therefore, a situation where the control section 210 cannot determine the coupling failure because the power supply voltage VDD is not supplied to the integrated circuit chip 200 is unlikely to occur. In addition, since the terminal Sv supplies the power supply voltage VDD from a position close to the center of the integrated circuit chip 200, the voltage drop of the power supply voltage VDD supplied to each section of the integrated circuit chip 200 is reduced, and the possibility of the integrated circuit chip 200 malfunctioning is reduced. Further, in the printed substrate 400, the pad Pv coupled to the terminal Sv is disposed more inward than the other pads, so that the pad Pv does not prevent the wiring from being drawn out from the other pads.

In addition, in the electronic device 1 according to the present embodiment, as illustrated in FIG. 6, in the printed substrate 400, the pads P5 and P6 are disposed closest to the side 302 of the base substrate 300, the pads P3, P4, and P8 are disposed at positions secondarily close to the side 302, and the pads P1, P2, and P7 are disposed at positions thirdly close to the side 302. Further, in the printed substrate 400, the pads P1 to P8 are disposed in a lattice shape, and a wide space is present between the pad P5 and the pad P6. Therefore, according to the electronic device 1 according to the present embodiment, in the printed substrate 400, four wirings W1 to W4 coupled to the pads P1 to P4, respectively, can be drawn out through a space between the pad P5 and the pad P6.

Further, according to the electronic device 1 according to the present embodiment, the interval between the pad P5 and the pad P6 can be widened by forming the pads P5 and P6 in an elliptical shape, so that the wirings W1 to W4 can be easily drawn out through the space between the pad P5 and the pad P6. In addition, since the interval between the pad P3 and the pad P4 can be widened by forming the pads P3 and P4 in an elliptical shape, the wiring W1 can be easily drawn out through a space between the pad P3 and the pad P4. Further, since the interval between the pad P4 and the pad P8 can be widened by forming the pad P8 in an elliptical shape, the wiring W2 can be easily drawn out through a space between the pad P4 and the pad P8.

The present disclosure is not limited to the present embodiment, and various modifications can be made within the scope of the gist of the present disclosure.

For example, in the present embodiment, although the package 330 of the semiconductor device 100 has been described as the ball grid array (BGA), the package 330 may be a surface-mount package other than the BGA, such as a system in package (SiP), a land grid array (LGA), and a wafer process in package (WPP). For example, when the package 330 is the LGA, the terminal of the semiconductor device 100 is a land provided on the package 330, in which the land, which is a terminal of the semiconductor device 100, is coupled to the pad 410 provided on the printed substrate 400 by the solder ball 310.

The embodiment has been described above, but the present disclosure is not limited to the embodiments and the modification examples, and can be implemented in various aspects without departing from the gist thereof. For example, the above-described embodiment can be combined as appropriate.

The present disclosure includes substantially the same configuration as the configurations described in the embodiments, for example, the configuration having the same function, method, and result, or configurations having the same object and effect. In addition, the present disclosure includes configurations in which non-essential parts of the configuration described in the embodiment are replaced. In addition, the present disclosure includes configurations that achieve the same operational effects or configurations that can achieve the same objects as those of the configurations described in the embodiment. In addition, the present disclosure includes configurations in which a known technology is added to the configurations described in the embodiment.

The following contents are derived from the above-described embodiment.

According to an aspect, an electronic device includes: a printed substrate; and a semiconductor device mounted on the printed substrate, in which the semiconductor device includes an integrated circuit chip that includes a determination section, and an integrated circuit substrate that is a substrate on which the integrated circuit chip is mounted, the integrated circuit substrate is provided with a plurality of terminals, the printed substrate is provided with a plurality of pads and a plurality of wirings, each of the plurality of terminals is coupled to each of the plurality of pads, the plurality of wirings include a constant potential wiring having a constant potential, a first pad of the plurality of pads is coupled to the constant potential wiring, a first terminal of the plurality of terminals is coupled to the first pad, and the determination section determines a presence or absence of a coupling failure between the semiconductor device and the printed substrate, based on a potential of the first terminal.

According to the electronic device, when the first terminal provided on the integrated circuit substrate of the semiconductor device is peeled off from the printed substrate, the first terminal is disconnected from the first pad and the potential of the first terminal is changed, so that the determination section can detect the coupling failure between the semiconductor device and the printed substrate based on the potential of the first terminal. Since the semiconductor device is built in with the determination section, the inspection of the coupling failure can be performed at any timing, and thus the coupling failure between the semiconductor device and the printed substrate caused by the age deterioration can be detected quickly. Further, since the semiconductor device is built in with the determination section, it is not necessary to mount a circuit for detecting the coupling failure between the semiconductor device and the printed substrate on the printed substrate, thereby reducing the cost of the printed substrate.

In the aspect of the electronic device, the integrated circuit substrate may have a first side, a second side opposite to the first side, a third side, and a fourth side opposite to the third side, none of the plurality of terminals may be disposed between the first terminal and the first side in a first direction from the second side toward the first side, and none of the plurality of terminals may be disposed between the first terminal and the third side in a second direction from the fourth side toward the third side.

According to the electronic device, when warpage occurs in the integrated circuit substrate of the semiconductor device due to age deterioration, the first terminal is provided at a corner of the integrated circuit substrate, which is a place where the probability of coupling failure is the highest, so that the accuracy of detecting the coupling failure can be improved.

In the aspect of the electronic device, the integrated circuit substrate may have a first side and a second side opposite to the first side, the plurality of wirings may include a power supply wiring, a second pad of the plurality of pads may be coupled to the power supply wiring, a second terminal of the plurality of terminals may be coupled to the second pad, a shortest distance between the first terminal and the first side may be shorter than a shortest distance between the first terminal and the second side, a shortest distance between the second terminal and the first side may be longer than the shortest distance between the first terminal and the first side, and a shortest distance between the second terminal and the second side may be longer than the shortest distance between the first terminal and the first side.

According to the electronic device, in the integrated circuit substrate of the semiconductor device, since the second terminal coupled to the power supply wiring is provided at a position closer to the center than the first terminal, the possibility that the second terminal is peeled off before the first terminal is low. Therefore, a situation where the determination section cannot determine the coupling failure because the power supply voltage is not supplied to the integrated circuit chip is unlikely to occur. Further, since the second terminal supplies the power supply voltage from a position close to the center of the integrated circuit chip, the voltage drop of the power supply voltage supplied to each section of the integrated circuit chip is reduced, and the possibility of the integrated circuit chip malfunctioning is reduced. Further, in the printed substrate, the second pad coupled to the second terminal is disposed more inward than the other pads, so that the second pad does not prevent the wiring from being drawn out from the other pads.

In the aspect of the electronic device, the determination section may determine the presence or absence of the coupling failure based on a logic level of the potential of the first terminal at a timing immediately after the second terminal reaches a power supply potential.

According to the electronic device, the determination section determines the presence or absence of the coupling failure each time the semiconductor device is started, so that the coupling failure due to age deterioration can be detected quickly.

In the aspect of the electronic device, the integrated circuit chip may include a detection section that outputs an interrupt signal to the determination section when the potential of the first terminal changes from a first logic level to a second logic level, and the determination section may determine that the coupling failure occurs when the interrupt signal is input.

According to the electronic device, the determination section does not need to determine the presence or absence of the coupling failure until the interrupt signal is input, so that other processing can be performed with priority.

According to the aspect, the electronic device may include: a recording device that performs recording on a medium; a transport motor that transports the medium; and a power supply circuit that supplies power to the transport motor, in which the determination section may stop supply of the power from the power supply circuit to the transport motor when a determination is made that the coupling failure occurs.

According to the electronic device, when the coupling failure occurs between the semiconductor device and the printed substrate, there is a concern that the recording device cannot normally perform recording on the medium, so that the medium is not wasted by stopping the supply of power to the transport motor.

In the aspect of the electronic device, a reset IC may be mounted on the printed substrate, the determination section may transmit a control signal to the reset IC when a determination is made that the coupling failure occurs, and the reset IC may receive the control signal and reset the semiconductor device.

According to the electronic device, when the determination section detects the coupling failure, the semiconductor device is reset, so that a possibility of malfunction due to the coupling failure is reduced.

What is claimed is:

1. An electronic device comprising:
a printed substrate; and
a semiconductor device mounted on the printed substrate, wherein
the semiconductor device includes
an integrated circuit chip that includes a determination section, and
an integrated circuit substrate that is a substrate on which the integrated circuit chip is mounted,
the integrated circuit substrate is provided with a plurality of terminals,
the printed substrate is provided with a plurality of pads and a plurality of wirings,
each of the plurality of terminals is coupled to each of the plurality of pads,
the plurality of wirings include a constant potential wiring having a constant potential,
a first pad of the plurality of pads is coupled to the constant potential wiring,
a first terminal of the plurality of terminals is coupled to the first pad, and
the determination section determines a presence or absence of a coupling failure between the semiconductor device and the printed substrate, based on a potential of the first terminal.

2. The electronic device according to claim 1, wherein
the integrated circuit substrate has a first side, a second side opposite to the first side, a third side, and a fourth side opposite to the third side,
none of the plurality of terminals is disposed between the first terminal and the first side in a first direction from the second side toward the first side, and
none of the plurality of terminals is disposed between the first terminal and the third side in a second direction from the fourth side toward the third side.

3. The electronic device according to claim 1, wherein
the integrated circuit substrate has a first side and a second side opposite to the first side,
the plurality of wirings include a power supply wiring,
a second pad of the plurality of pads is coupled to the power supply wiring,
a second terminal of the plurality of terminals is coupled to the second pad,
a shortest distance between the first terminal and the first side is shorter than a shortest distance between the first terminal and the second side,
a shortest distance between the second terminal and the first side is longer than the shortest distance between the first terminal and the first side, and
a shortest distance between the second terminal and the second side is longer than the shortest distance between the first terminal and the first side.

4. The electronic device according to claim 3, wherein
the determination section determines the presence or absence of the coupling failure based on a logic level of the potential of the first terminal at a timing immediately after the second terminal reaches a power supply potential.

5. The electronic device according to claim 1, wherein
the integrated circuit chip includes a detection section that outputs an interrupt signal to the determination section when the potential of the first terminal changes from a first logic level to a second logic level, and
the determination section determines that the coupling failure occurs when the interrupt signal is input.

6. The electronic device according to claim 1, further comprising:
a recording device that performs recording on a medium;
a transport motor that transports the medium; and
a power supply circuit that supplies power to the transport motor, wherein
the determination section stops supply of the power from the power supply circuit to the transport motor when a determination is made that the coupling failure occurs.

7. The electronic device according to claim 1, wherein
a reset IC is mounted on the printed substrate,
the determination section transmits a control signal to the reset IC when a determination is made that the coupling failure occurs, and
the reset IC receives the control signal and resets the semiconductor device.
